(19) United States
(12) Patent Application Publication
(10) Pub. No.: US 2014/0124182 A1
(43) Pub. Date: May 8, 2014

(54) COOLING SYSTEM OF POWER SEMICONDUCTOR DEVICE

(71) Applicant: SAMSUNG ELECTRO-MECHANICS CO., LTD., Suwon (KR)

(72) Inventors: Young Hoon KWAK, Suwon (KR); Jae Hyun Lim, Suwon (KR); Young Ki Lee, Suwon (KR); Chang Seob Hong, Suwon (KR)

(73) Assignee: SAMSUNG ELECTRO-MECHANICS CO., LTD., Suwon (KR)

(21) Appl. No.: 13/829,455

(22) Filed: Mar. 14, 2013

(30) Foreign Application Priority Data
Nov. 2, 2012 (KR) 10-2012-0123671

(51) Int. Cl. H01L 23/46

(52) U.S. Cl. CPC H01L 23/46
USPC 165/168

(57) ABSTRACT

Disclosed herein is a cooling system of a power semiconductor device. The cooling system of a power semiconductor device, which improves a cooling structure according to the related art to deprive heat generated from power devices while moving a working fluid introduced through an inlet to one direction and discharge the working fluid to an outlet, forms a branch inlet in a direction crossing a main inlet and additionally introduce the low-temperature working fluid through the branch inlet so as to be supplied to a channel to mix the working fluid supplied through the main inlet via the channel with the working fluid additionally introduced through the branch inlet around power devices, thereby improving a cooling effect.

### CROSS REFERENCE TO RELATED APPLICATION

This application claims the benefit of Korean Patent Application No. 10-2012-0123671, filed on Nov. 2, 2012, entitled “Cooling System Of Power Semiconductor Device” which is hereby incorporated by reference in its entirety into this application.

### BACKGROUND OF THE INVENTION

1. Technical Field

The present invention relates to a cooling system of a power semiconductor device.

2. Description of the Related Art

A power semiconductor device has been used for almost all home appliances, including a motor fan, an air conditioner, and a refrigerator and the use range thereof is being increased, for example, industrial and electrical devices, and the like. That is, the power semiconductor device has been almost essentially used for eco-friendly products by minimizing use power/energy.

Meanwhile, the high-capacity power semiconductor device that has been mainly used for industrial and electrical devices is light, small, and highly integrated, a cooling problem of a power device has been a large issued.

In order to solve the above problems, according to the related art, power devices including an insulated gate bipolar mode transistor (IGBT) having a high heat value are bonded on a cooling substrate and power devices are bonded on a cooling system by using a thermal grease or an inter-metal bonding method. Therefore, heat generated from the power devices are radiated through a cooling system that is attached to a bottom surface.

Patent Document 1 and Patent Document 2 disclose the cooling system according to the related art. That is, according to Patent Document 1, the cooling system has a cooling structure in which a plurality of cooling fins are formed in a heat sink base to circulate cooling water through a cooling path formed by an inverter case and a capacitor case, thereby depriving heat generated from the insulated gate bipolar transistor (IGBT) and discharging the heat through an outlet.

Further, according to Patent Document 2, in order to cool the power devices, an inlet and an outlet are formed on a base plate contacting an inner surface of a cooling substrate and an inlet manifold, an outlet manifold, and a micro channel that is supplied with a cooling medium from the inlet manifold and delivers the cooling medium to the outlet manifold are formed in the base plate.

However, the cooling system according to the related art, including Patent Document 1 and Patent Document 2, is configured to move a working fluid called cooling water or a cooling medium only in one direction and therefore, has limited cooling efficiency, such that it is difficult to reduce a temperature of the power device to a predetermined level or less.

That is, the cooling system disclosed in Patent Document 1 and Patent Document 2 are configured to discharge the working fluid, which is introduced through the inlet, through the outlet via the path (micro channel), such that the working fluid flows in one direction. Therefore, the cooling system according to the related art has a limitation in improving the cooling efficiency or reducing temperature to a predetermined level or less.

### PRIOR ART DOCUMENT

### Patent Document

(Patent Document 1) KR2006-0036400 A

(Patent Document 2) JP2008-522406 A

### SUMMARY OF THE INVENTION

The present invention has been made in an effort to improve a cooling system according to the related art that moves a working fluid only in one direction to change a flow of the working fluid introduced from several directions and reduce temperature, thereby solving a cooling problem.

Further, the present invention has been made in an effort to provide a cooling system of a power semiconductor device capable of easily cooling power devices.

According to a preferred embodiment of the present invention, there is provided a cooling system of a power semiconductor device, including: a cooling module that cools the power semiconductor device including power devices while discharging a working fluid introduced through a main inlet to a main outlet via a channel, wherein the cooling module includes a branch inlet that is formed in a direction crossing the main inlet and is additionally introduced with the working fluid.

The branch inlets may be configured as a pair and may be disposed at both sides of the cooling module based on the main inlet.

The pair of branch inlets may be disposed to be alternate with each other.

According to another preferred embodiment of the present invention, there is provided a cooling system of a power semiconductor device, including: a cooling substrate on which power devices are mounted; a heat sink that is bonded to one surface of the cooling substrate; and a cooling module that is mounted in the heat sink to cool the power devices, wherein the cooling module includes: a main inlet into which a working fluid is introduced; a channel that is formed in the cooling module so as to communicate with the main inlet; a main outlet that is formed in the cooling module so as to communicate with the channel and delivers the working fluid; and a branch inlet that is formed in a direction crossing the main inlet and is additionally introduced with the working fluid.

The heat sink may be a fin type heat sink in which cooling fins are formed in a heat sink base.

The cooling fins may be arranged in the heat sink base.

The cooling fin may have a quadrangular or circular section shape.

The branch inlet may be disposed between the cooling fins.

The branch inlets may be configured as a pair and may be disposed at both sides of the cooling module based on the main inlet.

The pair of branch inlets may be disposed in the cooling module so as to be alternate with each other.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view illustrating a cooling system of a power semiconductor device according to a preferred embodiment of the present invention;

FIG. 2 is a cross-sectional view illustrating the cooling system of a power semiconductor device according to a preferred embodiment of the present invention that is cut on a plane;

FIG. 3 is a perspective view illustrating a cooling system of a power semiconductor device according to another preferred embodiment of the present invention;

FIG. 4 is a cross-sectional view illustrating the cooling system of a power semiconductor device according to another preferred embodiment of the present invention that is cut on a plane; and

FIG. 5 is a cross-sectional view illustrating the cooling system of a power semiconductor device according to another preferred embodiment of the present invention that is cut on a side.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention are described in detail with reference to the accompanying drawings.

A cooling system of a power semiconductor device according to a preferred embodiment of the present invention changes a direction of a working fluid flowing in one direction through a main inlet into directions of a working fluid additionally introduced through several branch inlets and mix a low-temperature working fluid newly introduced with a high-temperature working fluid so as to easily cool power devices including an insulated gate bipolar transistor (IGBT) having a large heat value, thereby increasing a cooling effect.

That is, the cooling system is configured to be coupled with a cooling module cooling the power devices while discharging the working fluid introduced into the power semiconductor device through the main inlet to a main outlet via a channel and form a branch inlet in the cooling module in a direction crossing the main inlet to additionally introduce the working fluid.

The branch inlet is formed in a direction crossing the main inlet and is additionally introduced with the working fluid, such that the additionally introduced working fluid is mixed with the working fluid introduced through the main inlet in the channel. Further, the branch inlet is divided into several inlets to be supplied with the additionally introduced working fluid at various rates, such that the introduced amount and the discharged amount of the working fluid may be controlled to be the same.

Therefore, the fluid additionally introduced through the branch inlet is mixed with the working fluid introduced into the main inlet around the power device to change the flow of the working fluid flowing in one direction and move the working fluid toward the main outlet while reducing temperature.

Meanwhile, the main inlet, the main outlet, and the channel are formed to heat-exchange the introduced working fluid with the power devices and then, discharge the working fluid. That is, the working fluid introduced through the main inlet deprives heat generated from the power devices while passing through the channel and is discharged to the main outlet.

Meanwhile, the power semiconductor device may include power devices, a cooling substrate, and a heat sink In this configuration, the heat sink may adopt a general configuration or adopt a fin type heat sink in which a cooling fin is formed in the heat sink base.

Further, the cooling fins are arranged in the heat sink base in one or plural or a section thereof may have a quadrangle or a circle. Further, when the plurality of cooling fins are arranged in the heat sink base, the branch inlet is disposed between the cooling fins to facilitate the additional introduction of the working fluid.

Therefore, the working fluid additionally introduced through the branch inlet is mixed with the working fluid introduced through the main inlet in the channel to distribute the flow of the working fluid, thereby maintaining the power devices at low temperature.

Hereinafter, preferred embodiments of the present invention will be described in detail with reference to the accompanying drawings.

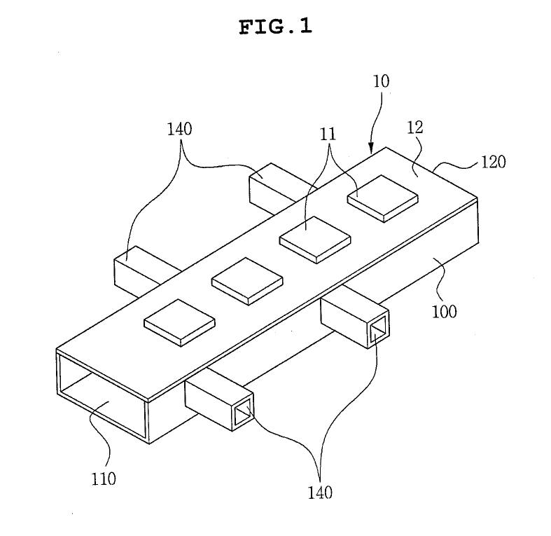

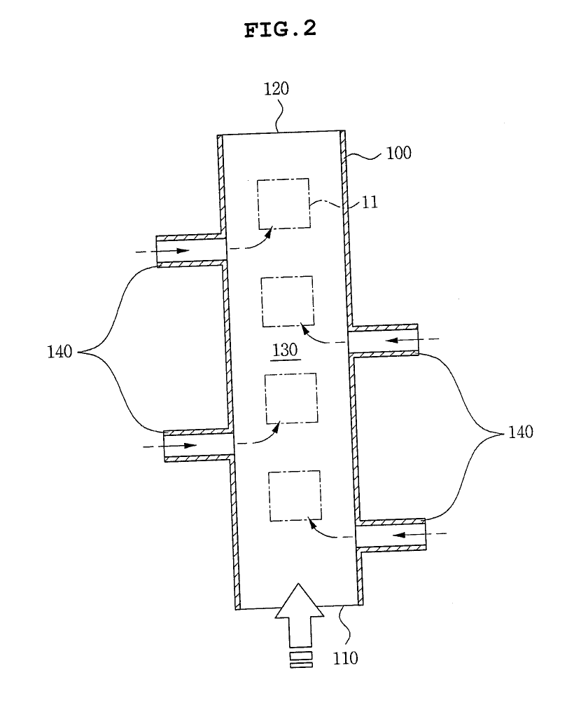

As illustrated in FIGS. 1 and 2, in the cooling system of a power semiconductor device according to the preferred embodiment of the present invention, power devices IGBT and FWD are mounted on an upper portion of a general cooling substrate 12 and a cooling module 100 is bonded on a lower portion of the cooling substrate 12.

The cooling module 100 has a main inlet 110 on one surface in a longitudinal direction and a main outlet 120 formed at an opposite side to the main inlet 110, such that a channel 130 is formed between the main output 120 and the main inlet 110. That is, the channel 130 communicates with the main inlet 110 and the main outlet 120 and is formed in the cooling module 100. Further, several branch inlets 140 are protruded so as to be alternately disposed at left and right sides of the cooling module 100 in a direction crossing the main inlet 110 at a right angle.

Therefore, the working fluid introduced through the main inlet 110 and introduced into the channel 130 and the working fluid additionally introduced through the branch inlet 140 and introduced into the channel 130 are mixed with each other in the channel 130 around the power devices 11, which is in turn introduced through the main inlet 110 and heat-exchanged with the power devices 11 while passing through the channel 130 to reduce the high-temperature working fluid, thereby cooling the power semiconductor device 10 including the power devices 11.

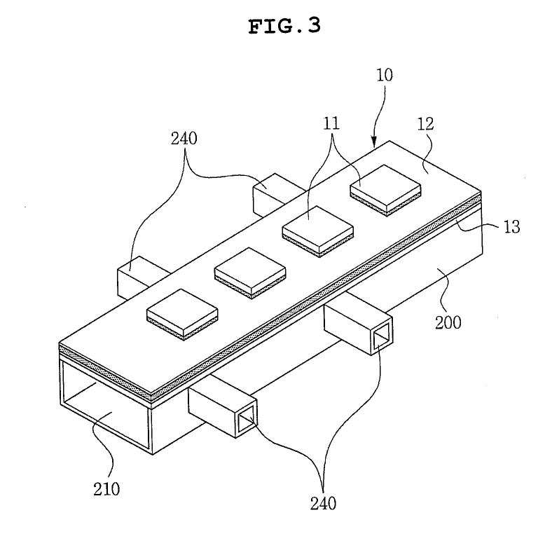

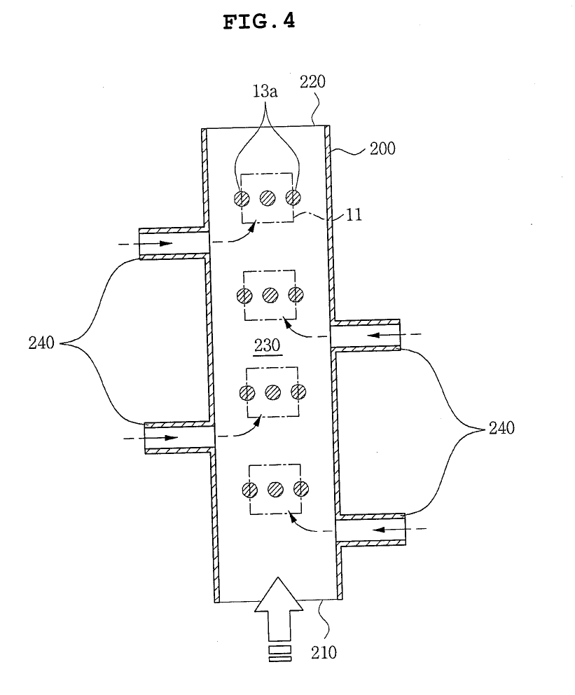

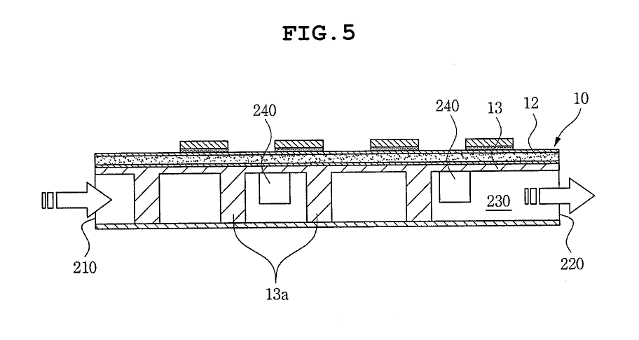

As illustrated in FIGS. 3 to 5, in a cooling system of a power semiconductor device according to another preferred embodiment of the present invention, the power devices IGBT and FWD are mounted on an upper portion of a direct bonded copper (DBC) as the cooling substrate 12 by a solder bonding method, the fin type heat sink 13 in which cooling fins 13a are arranged in a circular section shape is bonded to an opposite side of the power device 11, that is, the lower portion of the cooling substrate 12, and a cooling module 200 is bonded to the lower portion of the fin type heat sink 13 by a thermal grease or an inter-metal bonding method.

The cooling module 200 has a main inlet 210 on one surface in a longitudinal direction and a main outlet 220 formed at an opposite side to the main inlet 210, such that a channel 230 is formed between the main output 220 and the main inlet 210. That is, the channel 230 communicates with the main inlet 210 and the main outlet 220 and is formed in the cooling module 200. Further, several branch inlets 240 are protruded so as to be alternately disposed at left and right sides of the cooling module 200 in a direction crossing the main inlet 210 at a right angle.

In this case, the branch inlet 240 is disposed between the cooling fins 13a arranged at a predetermined interval so that the cooling fins 13a may not act as interference factors of the working fluid additionally introduced and the working fluids may be easily mixed around the power devices 11.

Therefore, the working fluid introduced through the main inlet 210 and introduced into the channel 230 and the working fluid additionally introduced through the branch inlet 240 and introduced into the channel 230 are mixed with each other in the channel 230 around the power devices 11, which is in turn introduced through the main inlet 210 and heat-exchanged with the cooling fins 13a while passing through the channel 230 to reduce the high-temperature working fluid, thereby cooling the power semiconductor device 10 including the power devices 11.

Table 1 shows working fluid/heat analysis results between the cooling system according to the related art and the cooling system of a power semiconductor device according to a preferred embodiment of the present invention.

Table 2 shows working fluid/heat analysis results between the cooling system according to the related art and the cooling system of a power semiconductor device according to another preferred embodiment of the present invention.

TABLE 3

| | Cooling | | |
|---|---|---|---|
| | Structure | | |
| | Analysis | | |
| | Result | | |
| | according | | |
| | to the | Branching inlet flow cooling sys. | |
| | Related art | Case A | Case B |
| Chip1 T_{AVG} [° C.] | 71 | 72 | 67 |
| Chip2 T_{AVG} [° C.] | 80 | 76 | 74 |
| Chip3 T_{AVG} [° C.] | 84 | 75 | 76 |
| Chip4 T_{AVG} [° C.] | 85 | 75 | 76 |
| Tmax [° C.] | 89 (chip4) | 78 (chip2&3) | 80 (chip3&4) |
| Tmin [° C.] | 61 | 61 | 57 |
| Inter-device Maximum | 28 | 17 | 23 |
| Temperature | | | |
| Difference [° C.] | | | |

Table 3 shows an average temperature (Min/Max) of each power device and results of temperature difference between the power devices.

The analysis is performed by setting the same volume flow rate (4.6×10⁻⁶ m³/s) based on the analysis conditions of the working fluid discharged through the main outlet. Table 1 shows results of conditions of a main inlet flow rate (1.0×10⁻⁶ m³/s) and a left branch inlet 1,2 & a right branch inlet 2 flow rate (1.2×10⁻⁶ m³/s) and Table 2 shows results of changing a flow rate to a main inlet flow rate (1.0×10⁻⁶ m³/s) and a left branch inlet 1,2 & a right branch inlet 2 flow rate (0.3×10⁻⁶ m³/s). This shows results of using the branch inlet flow rate while being controlled.

Further, as illustrated in Tables 1 and 2, when comparing the cooling system according to the related art with the results of temperature and flow rate, it can be appreciated that the maximum heat generation device is as low as about 9 to 10° C. and the maximum temperature difference between the power devices is lowered by about 20% to 40% (17 to 23° C.) than the heat generation system (28° C.) according to the related art to reduce the temperature difference between the power devices. Further, it can be appreciated that the average temperature of each power device has a difference of about 10° C.

According to the preferred embodiments of the present invention, the average temperature of the power device can be reduced. That is, it is possible to mix the low-temperature working fluid additionally introduced through the branch inlet with the working fluid supplied through the main inlet to distribute the flow of the working fluid, thereby maintaining the power devices at the low temperature. Further, it is possible to reduce the temperature of the power devices as much as about 20 to 40% as compared with the cooling system according to the related art, thereby reducing the change in the temperature between the power devices.

Meanwhile, the branch inlets are configured as a pair and are disposed at both sides of the cooling module based on the main inlet and are disposed so as to alternate with each other to efficiently mix the working fluid introduced through the main inlet with the working fluid additionally introduced through the branch inlets in the channel, thereby improving the cooling effect.

On the other hand, the cooling system is configured to include the cooling module for additionally introducing the working fluid into the power semiconductor device including the cooling substrate and the heat sink through the branch inlets and in particular, the cooling system is configured to include the fin type heat sink with the cooling fin as the heat sink, thereby further reducing the average temperature of the power devices. Therefore, the present invention can be very efficient for the power semiconductor device having a large heat value such as the industrial device, the vehicle, or the wind power plant and can be easily applied to a water cooling system and an air cooling system.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A cooling system of a power semiconductor device, comprising:
a cooling module that cools the power semiconductor device including power devices while discharging a working fluid introduced through a main inlet to a main outlet via a channel,
wherein the cooling module includes a branch inlet that is formed in a direction crossing the main inlet and is additionally introduced with the working fluid.

2. The cooling system as set forth in claim 1, wherein the branch inlets are configured as a pair and are disposed at both sides of the cooling module based on the main inlet.

3. The cooling system as set forth in claim 2, wherein the pair of branch inlets are disposed to be alternate with each other.

4. A cooling system of a power semiconductor device, comprising:
a cooling substrate on which power devices are mounted;
a heat sink that is bonded to one surface of the cooling substrate; and
a cooling module that is mounted in the heat sink to cool the power devices,
wherein the cooling module includes:
a main inlet into which a working fluid is introduced;
a channel that is formed in the cooling module so as to communicate with the main inlet;
a main outlet that is formed in the cooling module so as to communicate with the channel and delivers the working fluid; and
a branch inlet that is formed in a direction crossing the main inlet and is additionally introduced with the working fluid.

5. The cooling system as set forth in claim 4, wherein the heat sink is a fin type heat sink in which cooling fins are formed in a heat sink base.

6. The cooling system as set forth in claim 5, wherein the cooling fins are arranged in the heat sink base.

7. The cooling system as set forth in claim 6, wherein the cooling fin has a quadrangular or circular section shape.

8. The cooling system as set forth in claim 6, wherein the branch inlet is disposed between the cooling fins.

9. The cooling system as set forth in claim 8, wherein the branch inlets are configured as a pair and are disposed at both sides of the cooling module based on the main inlet

10. The cooling system as set forth in claim 9, wherein the pair of branch inlets are disposed in the cooling module so as to be alternate with each other.
